(19) United States
(12) Patent Application Publication
(10) Pub. No.: US 2003/0038330 A1
(43) Pub. Date: Feb. 27, 2003

(54) Semiconductor Device

(76) Inventor: Ayumi Obara, Kanagawa (JP)

Correspondence Address: KATTEN MUCHIN ZAVIS ROSENMAN, 575 MADISON AVENUE, NEW YORK, NY, 10022-2585, US

(21) Appl. No.: 10/227,648

(22) Filed: Aug. 23, 2002

(30) Foreign Application Priority Data
Aug. 27, 2001 (JP) 255869/2001

(51) Int. Cl. H01L 27/14

(52) U.S. Cl. 257/431

(57) ABSTRACT

A semiconductor device having a device region and a dimensional measurement pattern region according to the present invention, forms a device pattern, which is predicted to have dimensional variances due to the optical proximity effect according to a peripheral device pattern arrangement formed in the device region, and a dimensional measurement pattern, which has the same peripheral pattern arrangement in the dimensional measurement pattern region as the peripheral device pattern arrangement of the device region, and has the same shape as the device pattern.

### BACKGROUND OF THE INVENTION

1. Field of the Invention

The present invention relates to a semiconductor device. It particularly relates to a semiconductor device wherewith pattern miniaturization progresses and variation in ROM code pattern dimensions, which contributes to the optical proximity effect, are problems.

2. Description of the Prior Art

When the smallest dimensions of a pattern becomes, for example, smaller than the wavelength of exposing light, variation in resist pattern dimensions occurs after exposure/development due to the optical proximity effect. This is a phenomenon due to great changes in intensity of diffracted light according to the peripheral pattern arrangement.

Generally, there is a tendency for the pattern of interest to easily become larger than the target in the case of a high-density pattern, which has a large adjacent pattern number; and there is a tendency for the pattern of interest to easily become smaller than the target in the case of a low-density pattern, which has a small adjacent pattern number.

For this problem, techniques for correcting the reticle pattern such that the resist pattern (transfer pattern) is similar to the design pattern, namely techniques for performing optical proximity correction (OPC) during mask designing, are disclosed in Japanese Laid-open Patent Publication 2000-181045.

However, particularly with a masked ROM, code pattern arrangements to which dimension variation develops due to the optical proximity effect have become more multifaceted, and the amount of cell region code data has become immense due to the continuing considerable increase in capacity. Thus, manpower is required in the determination of defective patterns during resist pattern dimension measurement, which is performed for diffusing specific codes, thus causing the turn around time (TAT) to increase. In addition, since there are cases where detection oversights occur, the yield drops.

Accordingly, a first problem of the prior arts is that in resist pattern dimension measurement at the time of the above diffusing, the resist pattern dimensions must be measured by detecting the code patterns greatly influenced by the optical proximity effect, however, based on considerable increase in capacity, since the amount of cell region code data is immense, manpower is required for determining the corresponding code pattern arrangement.

A second problem is that in resist pattern dimension measurement at the time of the above diffusing, there is a probability of detection oversights of defective patterns due to diversification of pattern combinations, and also the fact that the amount of cell region code data is immense despite that the code pattern arrangement greatly influenced by the optical proximity effect can be projected from evaluation results. When a detection oversight occurs, the yield drops due to the generating of defects.

A third problem is that dimension variations for every code, which occur due to the optical proximity effect according to the pattern for each code, can not be monitored using unique dimensional measurement patterns since pattern arrangements of the code patterns tend to differ for every user code.

Moreover, even when patterns are miniaturized, variations of the finished dimensions in places where the optical proximity effect has occurred even between each reticle (between masks) are causes for the yield to drop.

Accordingly, a fourth problem of the prior arts is that regardless of many code reticles having dimensional measurement patterns, they are not measurement patterns allowing for influences of the optical proximity effect, and thus not enabling to monitor as far as the dimension variations, which are due to the optical proximity effect, and reticle accuracy drops.

Accordingly, the present invention aims to provide a semiconductor device, and a semiconductor device manufacturing method or reticle, which allow resist pattern dimensions due to the optical proximity effect to be easily grasped regardless of code pattern arrangements diversifying, and the amount of cell region code data becoming immense.

### BRIEF SUMMARY OF THE INVENTION

### OBJECTS OF THE INVENTION

The present invention aims to provide a semiconductor device, which allows resist pattern dimensions due to the optical proximity effect to be easily grasped regardless of code pattern arrangements diversifying, and the amount of cell region code data becoming immense.

### SUMMARY OF THE INVENTION

A semiconductor device having a device region and a dimensional measurement pattern region according to the present invention, forms a device pattern, which is predicted to have dimensional variances due to the optical proximity effect according to a peripheral device pattern arrangement formed in the device region, and a dimensional measurement pattern, which has the same peripheral pattern arrangement in the dimensional measurement pattern region as the peripheral device pattern arrangement of the device region, and has the same shape as the device pattern.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIGS. 1A and 1B are top views illustrating a semiconductor chip coded with a user code A in a first embodiment of the present invention;

FIGS. 2A and 2B are top views illustrating a reticle, which is used for coding the user code A of FIG. 1;

FIGS. 3A and 3B are top views illustrating a semiconductor chip coded with a user code B of the first embodiment of the present invention;

FIGS. 4A and 4B are top views illustrating a reticle, which is used for coding the user code B of FIG. 3;

FIG. 5 is a top view illustrating a ROM code region, an etching terminal region and a dimensional measurement pattern arrangement region of a semiconductor chip according to the embodiment of the present invention;

FIG. 6 is a top view illustrating the interior portions of the ROM code region and dimensional measurement pattern arrangement region of the embodiment of the present invention;

FIG. 7 is a flowchart showing manufacturing flow according to the embodiment of the present invention;

FIGS. 8A and 8B are top views illustrating a second embodiment of the present invention;

FIG. 9 is a top view illustrating an entire semiconductor chip of a third embodiment of the present invention;

FIG. 10 is a top view illustrating an entire semiconductor chip of a fourth embodiment of the present invention;

FIG. 11 is a top view illustrating a fifth embodiment of the present invention, showing four entire semiconductor chips adjacent to one another in a wafer state;

FIG. 12 is a top view illustrating a sixth embodiment of the present invention, showing four entire semiconductor chips adjacent to one another in a wafer state;

FIGS. 13A through 13D are top views respectively illustrating examples of patterns A through D of FIG. 12; and

FIG. 14 is a top view illustrating a seventh embodiment of the present invention.

### DETAILED DESCRIPTION OF THE INVENTION

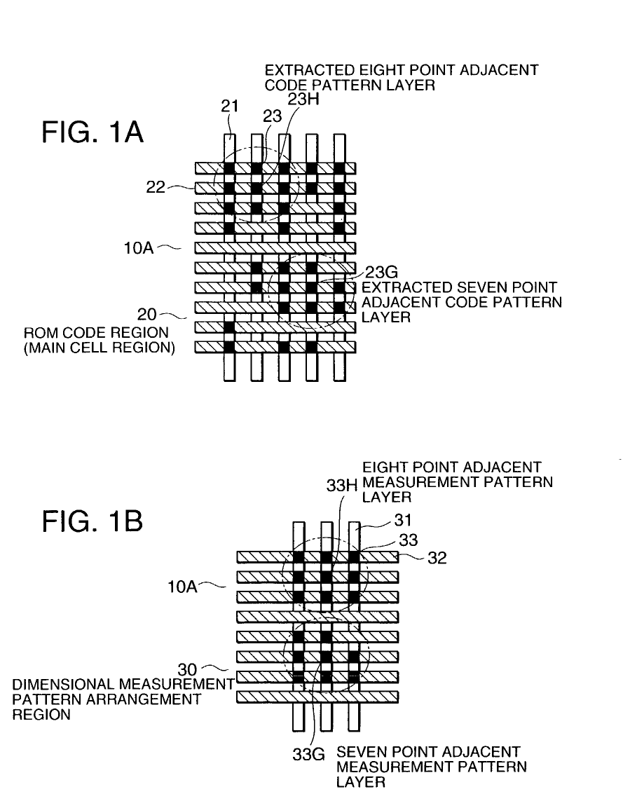

Hereafter, the present invention is described in conjunction with referencing the drawings. FIGS. 1A and 1B are top views illustrating a semiconductor chip coded with a user code A in the first embodiment of the present invention; where FIG. 1A shows a ROM code region (main cell region), and FIG. 1B shows a dimensional measurement pattern arrangement region.

To begin with, referencing FIG. 1A, a plurality of polysilicon interconnect layers (lower right hatching) 22, which have the same intervals therebetween, exist extending vertically in the drawing upon a thick field insulating film and a thin gate insulating film upon a P-type surface region in a ROM code region (main cell region) 20 of a semiconductor chip 10A.

Furthermore, these plurality of polysilicon interconnect layers 22 and a plurality of diffusion zones (white lattice) 21, which are doped with an N-type impurity using the field insulating film as a mask, exist extending horizontally in the drawing having the same intervals therebetween.

Accordingly, between the diffusion zones 21 are field insulating film; the diffusion zones 21 between the polysilicon interconnect layers 22 are of N-type; and the diffusion zones 21, which are below the polysilicon interconnect layers 22 via the gate insulating layers, are all of P-type prior to coating, and are thus all enhancement-type prior to coating.

A silicon oxide film is formed overall in this condition and reserved. Then, after the code is entered from the user (customer), in order to match with that code, namely so as to meet at the user code A in FIG. 1, a reticle (for example, a mask for a one-fifth reduction stepper) is created, a negative resist is coated upon the silicon oxide film of the wafer-state semiconductor chip 10A, and by executing exposure/development using this reticle as a mask, apertures are formed in the negative resist, which is upon the selected channel region (diffusion zone region below the polysilicon interconnect layer).

Then, a semiconductor device of a masked ROM, which fulfills the user code A, may be obtained by selectively etching the silicon oxide film using this negative resist as a mask until reaching a polysilicon interconnect layer, implanting N-type impurity ions using the remaining silicon oxide film and negative resist pattern as a mask, and subsequent thermal processing so as for this selected channel region to become of N-type and depletion-type.

Here, the apertures formed in the negative resist upon the selected channel region in the ROM code region 20 are referred to as code pattern layers (black squares) 23.

With the user code A of this embodiment, among the code pattern layers 23, an eight point adjacent code pattern layer 23H, which is surrounded by eight other code pattern layers 23, and a seven point adjacent code pattern layer 23G, which is surrounded by seven other code pattern layers 23, are recognized as having a tendency of the variation of resist pattern dimensions to increase due to the optical proximity effect, whereby necessity of measuring dimensions thereof is determined. In this case, the reticle is developed so as to cope therewith.

As shown in FIG. 1B, with this reticle, dimensional measurement pattern layers (black squares) 33 are formed in a dimensional measurement pattern arrangement region 30 of the same semiconductor chip 10A.

Namely, a plurality of polysilicon interconnect layers 32, which have the same shape, same material, and same intervals as the polysilicon interconnect layers 22 of the ROM code region 20, are formed in the dimensional measurement pattern arrangement region 30, and a plurality of diffusion zones 31, which have the same shape, same impurity concentration, and same intervals as that of the diffusion zones 21 of the ROM code region 20. Furthermore, the field insulating film and gate insulating film of the dimensional measurement pattern arrangement 30 are the same as that of the ROM code region 20.

Then, when developing the user code A reticle, even in the dimensional measurement pattern arrangement 30, similarly to the eight point adjacent code pattern layer 23H and seven point adjacent code pattern layer 23G, each (one combination) of an eight point adjacent measurement pattern layer 33H, which is surrounded by eight other pattern layers 33, and a seven point adjacent measurement pattern layer 33G, which is surrounded by seven other pattern layers 33, are formed.

With the code pattern of user code A as such, since the pattern arrangement to which dimension variation due to the optical proximity effect is projected is the eight point adjacent code pattern layer 23H and the seven point adjacent code pattern layer 23G, they are extracted and reflected in the dimensional measurement pattern arrangement region 30, respectively forming the eight point adjacent measurement pattern layer 33H and the seven point adjacent measurement pattern layer 33G. Then, the pattern arrangement to which dimension variation occurs by coming under the influence of the optical proximity effect may be projected through prior evaluation.

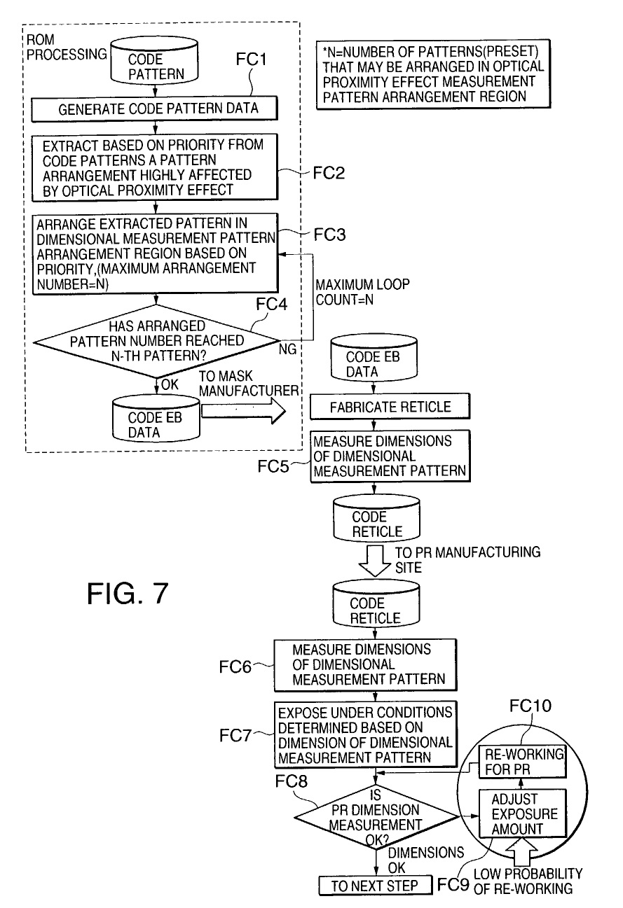

Since the generated form of the code pattern differs for every code, the present invention is one that verifies in advance the code pattern arrangement to which dimension variations classified by adjacency number, distance to the adjacent code pattern layer and the like are projected, detects the corresponding pattern from the code mask patterns, which are generated during ROM processing, and arranges the detected corresponding code pattern as a dimensional measurement pattern in the master data according to priority, which will be later described in detail while referencing FIG. 7.

It should be noted that in FIG. 1, the group of target code pattern layers in the ROM code region and the group of target pattern layers in the dimensional measurement pattern arrangement region are shown surrounded by two-dot chain line circles.

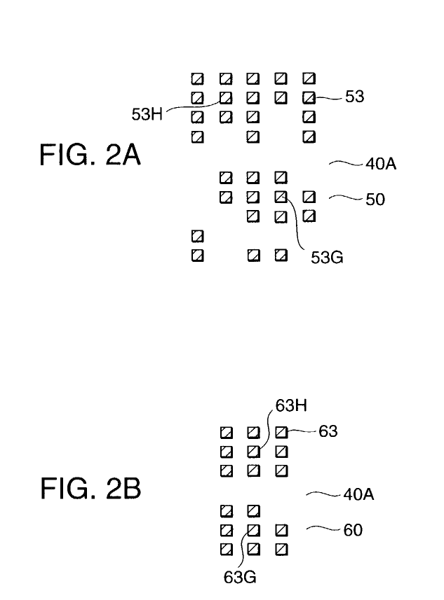

FIGS. 2A and 2B are top views illustrating a reticle 40A, which is used for coding the user code A of FIG. 1; where 2A shows a reticle pattern region 50 for the ROM code region, and 2B shows a reticle pattern region 60 for the dimensional measurement pattern arrangement region.

In the reticle pattern region 50 for the ROM code region, reticle patterns 53, which are used for forming the code pattern layers 23 of FIG. 1, are formed, and includes reticle patterns 53G and 53H, which are used for forming the seven point adjacent code pattern layer 23G and eight point adjacent code pattern layer 23H of FIG. 1.

Meanwhile, in the reticle pattern region 60 for the dimensional measurement pattern arrangement region, reticle patterns 63, which are used for forming the dimensional measurement pattern arrangement region pattern layers 33 of FIG. 1, are formed, and includes reticle patterns 63G and 63H, which are used for forming the seven point adjacent measurement pattern layer 33G and eight point adjacent measurement pattern layer 33H of FIG. 1.

The reticle patterns 53 (53G, 53H) and 63 (63G, 63H) in FIG. 2 are configured with shielding film, and each of the sides are five times (in the case of the one-fifth reduction stepper) the size of the resist patterns 23 (23G, 23H) and 33 (33G, 33H) in FIG. 1, respectively.

In manufacturing according to the present invention, variation in dimensions between reticles may be controlled by measuring the dimensions of the reticle patterns 63G and 63H of the dimensional measurement pattern arrangement region, checking the finished condition of the fabricated reticle patterns adversely influenced particularly from the optical proximity effect, and correcting light exposure in accordance with the deviation from the design center dimensions. Then, after exposure/development, the resist patterns 33G and 33H of FIG. 1 are measured and the adverse influence of the optical proximity effect are checked, however, details will be described by referencing FIG. 7.

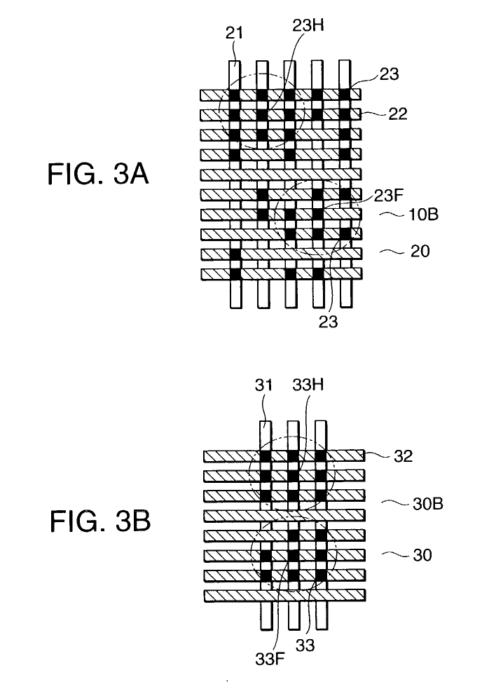

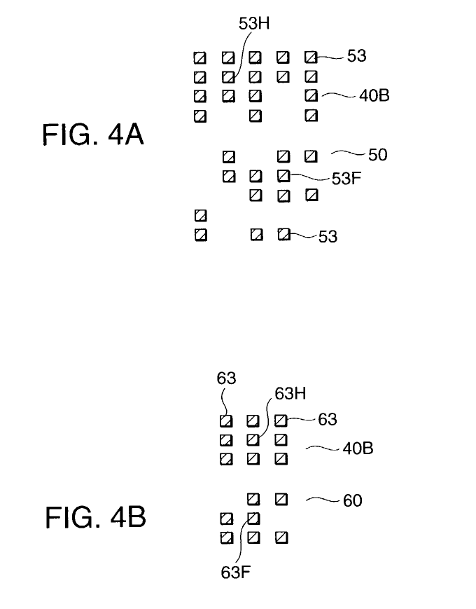

FIGS. 3A and 3B are top views illustrating a semiconductor chip coded with a user code B according to the first embodiment of the present invention, and FIGS. 4A and 4B are top views illustrating a reticle, which is used for coding the user code B. It should be noted that in FIG. 3 and FIG. 4, the same or similar elements as those in FIG. 1 are given the same symbols, and thus duplicate descriptions will be omitted.

With user code B, in the ROM code region 20 of a semiconductor chip 10B, an eight point adjacent code pattern layer 23H and a six point adjacent code pattern layer 23F, which is surrounded by six other code pattern layers 23, are recognized as having a tendency of the variation of resist pattern dimensions to increase due to the optical proximity effect, whereby necessity of measuring dimensions thereof is determined. Accordingly, each (one combination) of an eight point adjacent measurement pattern layer 33H and a six point adjacent measurement pattern layer 33F, which is surrounded by six other pattern layers 33, are formed within the dimensional measurement pattern arrangement region 30 of the same semiconductor chip 10B.

For this purpose, as shown in FIG. 4, reticle patterns 53, which are used for forming the code pattern layers 23 of FIG. 3, are formed on the reticle 40B, and includes reticle patterns 53F and 53H, which are used for forming the six point adjacent code pattern layer 23F and eight point adjacent code pattern layer 23H of FIG. 3.

Meanwhile, in the reticle pattern region 60 for the dimensional measurement pattern arrangement region, reticle patterns 63, which are used for forming the pattern layers 33 in the dimensional measurement pattern arrangement region of FIG. 1, are formed, and includes reticle patterns 63F and 63H, which are used for forming the six point adjacent measurement pattern layer 33F and eight point adjacent measurement pattern layer 33H of FIG. 3.

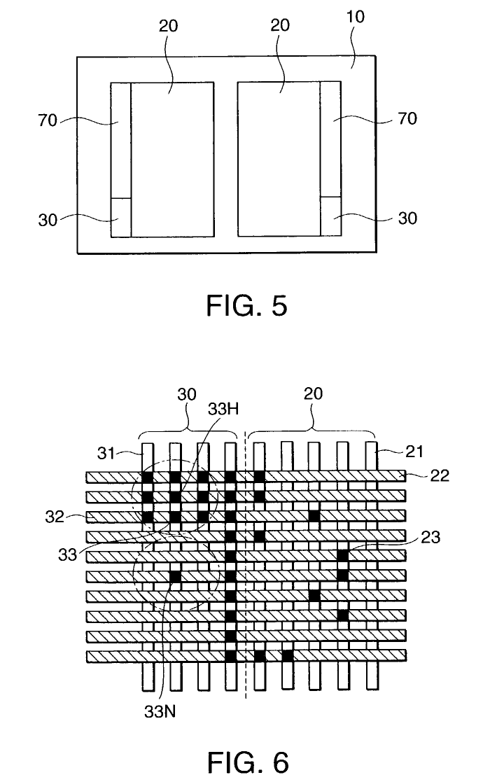

FIG. 5 is a top view illustrating the entire semiconductor chip 10 according to the embodiment of the present invention, which includes two locations of the ROM code region 20, two locations of an etching dummy cell 70, and two locations of the dimensional measurement pattern arrangement region 30 according to the present invention.

A dummy pattern, which has no connection to circuit operations, is formed with identical design standards as the main cell in the etching dummy cell region 70 such that predetermined etching patterning is performed to the main cell.

FIG. 6 is a top view illustrating the interior portions of the ROM code region 20 and the dimensional measurement pattern arrangement region 30 according to the embodiment of the present invention. It should be noted that in FIG. 6, the same or similar elements as those in FIG. 1 are given the same symbols.

In FIG. 6, the eight point adjacent code pattern layer (high-density pattern) and code pattern layer without any adjacency (low-density pattern) in the ROM code region 20 according to a user code are recognized as having a tendency of the variation of resist pattern dimensions to increase due to the optical proximity effect, whereby necessity of measuring dimensions thereof is determined. Accordingly, each (one combination) of the respective eight point adjacent measurement pattern layer 33H and no-adjacency measurement pattern layer 33N are formed in the dimensional measurement pattern arrangement region 30 of the same semiconductor chip.

FIG. 7 is a flowchart showing the manufacturing flow according to the embodiment. In a code pattern generating step FC1, ROM processing is implemented based on code data ordered by a user, generating a code mask pattern. In a varied pattern extracting step FC2, a code pattern arrangement, which allows variation in dimensions due to the optical proximity effect to easily occur, is extracted from the generated code patterns.

When extracting, the patterns that are projected as greatly varying in dimensions, which are due to the optical proximity effect, are extracted from the results of the prior evaluation, however, priority is established for the to-be-extracted pattern arrangements, whereby the extraction procedure is implemented in the decreasing order of priority.

As an extraction example, an extracting method of the low-density/high-density patterns, which are representative patterns of the optical proximity effect, is described.

In the case of extracting the high-density pattern, the patterns are extracted from the code patterns of interest in the decreasing order of the number of adjacent patterns. When a pattern with at least five point adjacency to a code pattern of interest is defined as the high-density pattern, extraction is performed in the decreasing order of adjacency number from eight point adjacency, which is the largest adjacency number, seven point adjacency, six point adjacency and five point adjacency. Next, extraction is performed not only by adjacency number, but in the decreasing order of pattern numbers that exist within the range where the code pattern of interest may be influenced. In the case of extracting low-density patterns, extraction is performed in the increasing order of the number of pattern arrangements in a fixed area around the code pattern of interest. These arrangements of varied patterns and extraction order for to-be-extracted-objects are those determined based on evaluation results.

After dimension-varied pattern extraction, in a pattern arranging step FC3, the extracted code patterns are then arranged in the dimensional measurement pattern arrangement region. When arranging thereof, they are arranged in the decreasing order of priority up to the Nth number. N is the number of patterns that may be arranged in the dimensional measurement pattern arrangement region, and is preset.

Next, in a pattern arrangement number checking step FC4, it is determined whether the number of arranged patterns has reached the Nth number. In the case where the pattern number has reached the Nth number, the pattern arrangement processing is concluded, outputting code EB data. Code EB data is what becomes the input file during reticle manufacturing, and is what is converted into mask pattern data through ROM processing based on the user code. Optical proximity effect dimensional measurement patterns are also included in this embodiment.

Furthermore, in the case where the pattern number has not reached the Nth number, in the pattern arranging step FC3 once again, the patterns already extracted are arranged in the dimensional measurement pattern arrangement region in the decreasing order of priority.

In the case where the number of times of looping from the pattern number checking step to the varied pattern arranging step has reached N times where N denotes the maximum number, processing is concluded, outputting the code EB data. Thus, in the case where there is no corresponding pattern in the pattern extracting step, code patterns are not arranged in the dimensional measurement pattern arrangement region since no patterns are detected to which dimension variation develops due to the optical proximity effect. In the pattern extracting step, when only one pattern is extracted, the entire dimensional measurement pattern arrangement region is to be embedded with that pattern alone. However, the method of pattern embedding the vacant regions is merely an example, whereby appropriately changing thereof is allowed.

In a reticle dimension measuring step FC5 during reticle fabrication, dimensions of the dimensional measurement pattern that is registered in step FC3 are measured, verifying with designated precision that the reticle is fabricated. Accordingly, precision maybe raised by suppressing variations of the reticle.

Subsequently, this reticle is sent to a site where the PR step is executed, namely a manufacturing site or a factory whereat the step of forming photo resist patterns is executed for doping impurities into an appropriate place for the user code.

In a reticle dimension measuring step FC6 prior to exposure, dimensions of the dimensional measurement pattern that is registered in step FC3 are measured. Namely, dimensions of the reticle pattern in the reticle dimensional measurement pattern arrangement region are measured. In a PR exposing step FC7, the exposure conditions appropriate for the reticle code pattern measured in FC6 are determined based on the relationship between the PR exposure amount and reticle dimensions obtained through the pre-evaluation so as to execute exposure thereto. After development, in a PR dimension measuring step FC8, dimensions of pattern layers in the dimensional measurement pattern arrangement region of the photo resist (PR), which is formed using the reticle patterns of the reticle dimensional measurement pattern arrangement region, are measured. Namely, the photo resist aperture dimensions (code aperture size) of that position are verified. In the dimensional measurement pattern registering step FC3, since patterns highly affected by the optical proximity effect are preset as measuring patterns, and are arranged in a fixed position, manpower necessary for detection of defective patterns is reduced, and detection oversights occurring are eliminated.

In the case where dimensions of the measurement pattern highly affected by the optical proximity effect are not within predetermined limits even if exposing is performed with the amount of exposure that is corrected based on the reticle dimensions in step FC7, all of the resists are eliminated, repeating the work for performing resist application and development. At this time, adjustment of exposure amount or adjustment of resist film thickness is performed so that dimensions fall within specified limits regardless of the measurement pattern highly affected by the optical proximity effect (FC9, FC10). According to the present invention, since exposing is performed under the exposure conditions, which take into consideration the reticle finished conditions, the probability of repeating the work by means of FC9 and FC10 reduces.

When dimensions of the resist measurement pattern are within the specified limits, they are sent to the following step, impurity ions are doped using this resist pattern as a mask, and through subsequent thermal processing, a mask ROM that fulfills the user code from a customer may be obtained.

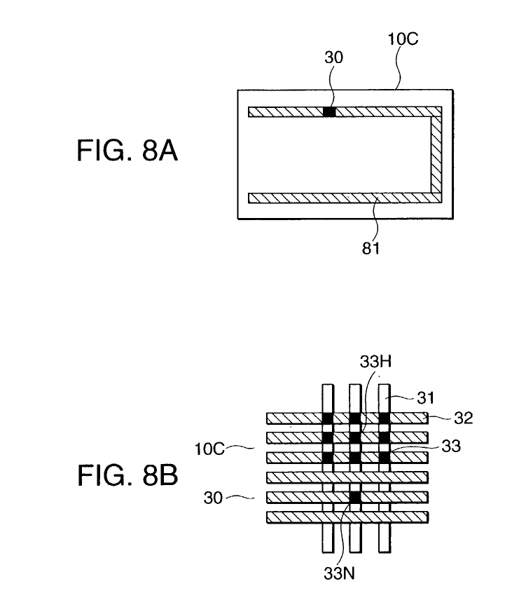

In the following illustrated FIG. 8 through FIG. 14, the same or similar elements as those in FIG. 1 are given the same symbols, and thus duplicate descriptions will be omitted as much as possible.

FIGS. 8A and 8B are top views illustrating a second embodiment of the present invention; wherein FIG. 8A shows an entire semiconductor chip, and FIG. 8B shows the internal portions of the dimensional measurement pattern arrangement region.

A dimensional measurement pattern arrangement region 30 is arranged below a power source line, or metal interconnect 81 of a signal line, whereat each (one combination) of an eight point adjacent measurement pattern layer 33H and a no-adjacency measurement pattern layer 33N are respectively formed.

In this embodiment, it is necessary to form the measurement pattern layer so as not to affect connection to the metal interconnect, however, there is an advantage where the integrated density of the semiconductor chip does not reduce even if the dimensional measurement pattern arrangement region 30 is provided. The advantage exists based on the premise that it is not a switching-over pattern through interconnects.

In this drawing, the case where the dimensional measurement pattern is arranged below the power source line is illustrated, however, arranging below metal interconnect such as a signal line, or arranging at the same time as executing a step that has no connection to other code diffusion is possible, whereby a result of arranging patterns without influencing semiconductor chip size may be obtained.

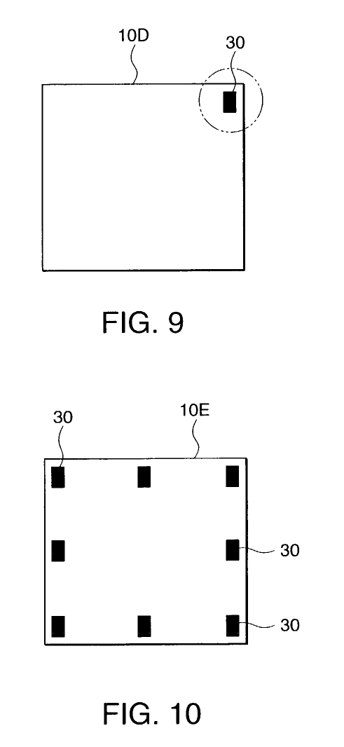

FIG. 9 is a top view illustrating a third embodiment of the present invention, showing an entire semiconductor chip. A dimensional measurement pattern arrangement region 30 is arranged in a corner region, which is dead space of a semiconductor chip 10D. Since the dimensional measurement pattern of the present invention is not one for transistor characteristics to be measured, the dead space may be effectively used with few limits in determining arrangement location. Generally, in order for the semiconductor chip corner region to avoid influences of a heat cycle test, arrangement of active devices is prohibited, and certain limitations are provided to the metal interconnect layer design. However, since the dimensional measurement pattern of this embodiment does not include metal interconnect layers nor measure transistor characteristics, arranging in the semiconductor chip corner region thereof is possible.

FIG. 10 is a top view illustrating a fourth embodiment of the present invention, showing an entire semiconductor chip 10E. A plurality of dimensional measurement pattern arrangement regions 30 are arranged by distributing on the periphery of the semiconductor chip 10E, forming the same measurement pattern layers or the same measurement pattern layer group in the respective dimensional measurement pattern arrangement regions 30.

In this manner, identical dimensional measurement patterns are arranged over the entire surface in the semiconductor chip, and thus may obtain a result such that the dimension variations within the semiconductor chip can be monitored.

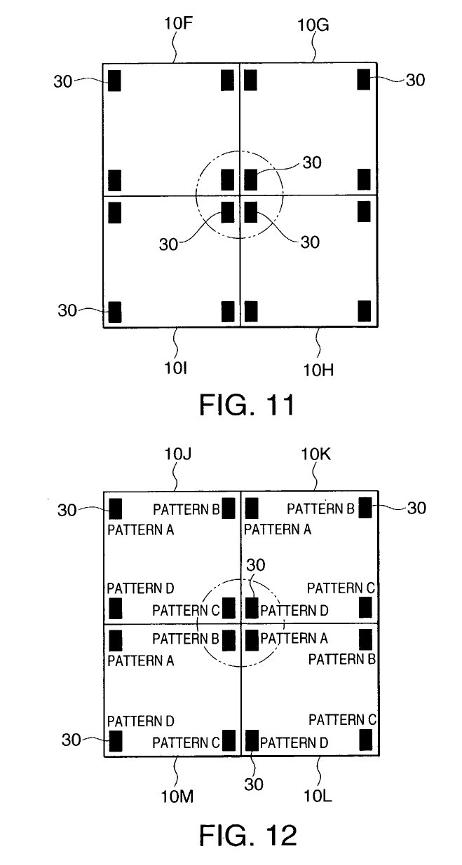

FIG. 11 is a top view illustrating a fifth embodiment of the present invention, showing four entire semiconductor chips adjacent to one another in a wafer state.

The dimensional measurement pattern arrangement regions 30 are respectively arranged in the four corners of semiconductor chips 10F, 10G, 10H, and 10I. In this manner, since the dimensional measurement pattern arrangement regions 30, which include formed identical dimensional measurement pattern layers, are arranged in the four corners within the semiconductor chips, even upon a wafer where a plurality of semiconductor chips are arranged, the PR dimensions of the four corners of each semiconductor chip may be easily measured within the severely restricted measurement limit, which is indicated by a two-point chain line circle, and variations in the pattern dimensions among the semiconductor chips upon the wafer may be easily monitored.

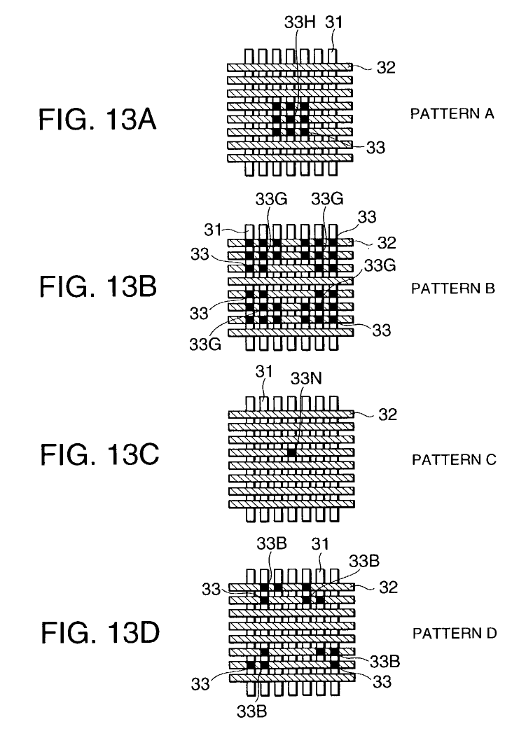

FIG. 12 is a top view illustrating a sixth embodiment of the present invention, showing four entire semiconductor chips adjacent to one another in a wafer state. Furthermore, FIGS. 13A through 13D are top views respectively illustrating examples of patterns A through D of FIG. 12.

Dimensional measurement pattern arrangement regions 30 are arranged in the respective four corners of the four semiconductor chips 10J, 10K, 10L, and 10M, which are adjacent to one another in a wafer state, forming pattern A, pattern B, pattern C, and pattern D, respectively.

For example, as illustrated in FIG. 13, pattern A is a pattern for measuring dimensions of the eight point adjacent measurement pattern layer 33H; pattern B is a pattern for measuring dimensions of the seven point adjacent measurement pattern layer 33G; pattern C is a pattern for measuring dimensions of the no-adjacency measurement pattern layer 33N; and pattern D is a pattern for measuring dimensions of the two point adjacent measurement pattern layer 33B.

Since four types of dimensional measurement patterns are arranged in the four corners in the semiconductor chips as such, even upon the wafer where a plurality of semiconductor chips are arranged, four types of reticle dimension patterns may be easily measured within the severely restricted measurement limit, which is indicated by a two-point chain line circle, and the manpower required for PR dimensional measurement upon the wafer may be reduced.

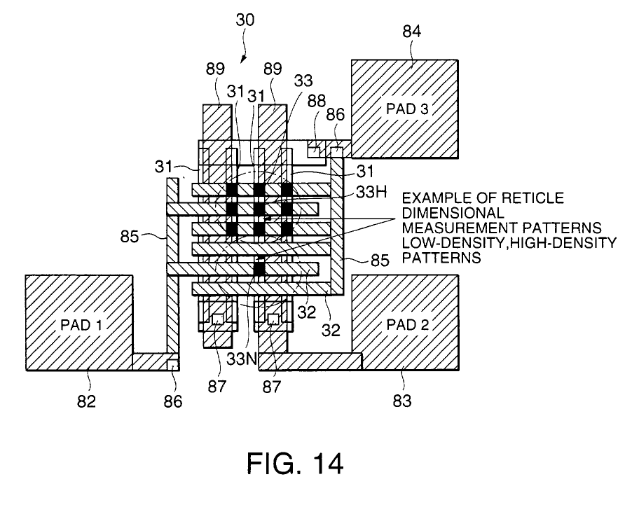

FIG. 14 is a top view illustrating a seventh embodiment of the present invention. A first electrode pad (PAD 1) connects with a polysilicon interconnect 85 via a contact region 86 on the left side of the drawing, wherefrom two polysilicon interconnect layers 32, which are gate electrodes, exist consecutively extending from left to right in the drawing.

A second electrode pad (PAD 2) is a drain terminal for a selected cell, and is connected via a contact region 87 to a metal interconnect 89, which is a digit line, on the right side of the drawing, and to two diffusion zones 31 at the lower end of the drawing.

A third electrode pad (PAD 3) connects via a contact region 86 with a polysilicon interconnect 85 on the right side of the drawing, wherefrom three polysilicon interconnect layers 32, which are gate electrodes, exist consecutively extending from right to left in the drawing. Moreover, this third electrode pad is connected via a contact region 88 to four diffusion zones 31 at the top of the drawing.

Here, a no-adjacency measurement pattern layer 33N as a low-density pattern and an eight point adjacent measurement pattern layer 33H as a high-density pattern are provided, enabling measurement of the transistor characteristics in the second diffusion zone to the right of these measurement pattern layer positions. It should be noted that the left side metal interconnect 89, which is connected at the lower end of the drawing to the four diffusion zones 31 via the contact region 88, is a dummy digit line.

The dimensional measurement patterns of this embodiment have the same layer configuration as the ROM cell regions as such. As for arrangement of the measurement pattern layers, as with the other embodiments, extraction is performed from the dimensional variance projected patterns for every code; however, in the drawing, the low-density/high-density patterns, which are a representative example of the optical proximity effect, are used.

With the present dimensional measurement patterns, supplying electrical potential to each of the gate, source and drain terminals is possible. Accordingly, there is a result of allowing measurement of transistor characteristics of the code patterns, which are varied due to the optical proximity effect.

As described in the foregoing, according to the present invention, such results as described below take effect.

The first result is that a dimensional measurement pattern based on the actual pattern may be created by extracting from the code patterns that differ for every code, a pattern wherewith dimension variation occurs due to the optical proximity effect, and providing it as that dimensional measurement pattern.

The second result is that since reticle dimension variations due to the optical proximity effect may be monitored through measuring the above-mentioned dimensional measurement pattern during reticle fabrication, reticle accuracy may be improved and variations between the reticles may be suppressed.

The third result is that by measuring the above-mentioned dimensional measurement pattern prior to PR exposure for selectively doping an impurity and executing adjustment of exposure amount in accordance with the code reticle dimensions, the exposure accuracy is improved thereby reducing repeated work due to reticle dimension variation, and improving the throughput of the coding step.

The fourth result is that in PR dimensional measurement, which is made for selectively doping an impurity, the manpower required for detecting defective patterns may be reduced since the worst pattern of the dimension variations, which are due to the optical proximity effect, maybe easily monitored through measuring the resist patterns with the above-mentioned dimensional measurement pattern. Furthermore, decreasing oversights in detecting defective patterns leads to improvements in yield.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A semiconductor device, which has a device region and a dimensional measurement pattern region, comprising:
a device pattern, which is predicted to have dimensional variances due to the optical proximity effect according to a peripheral device pattern arrangement formed in said device region, and a dimensional measurement pattern, which has the same peripheral pattern arrangement in said dimensional measurement pattern region as said peripheral device pattern arrangement of said device region and has the same shape as said device pattern.

2. The semiconductor device, according to claim 1, wherein
said device region is a ROM code region of a masked ROM, and said device pattern is a pattern specified by a user code.

3. The semiconductor device, according to claim 1, wherein
a plurality of dimensional measurement patterns, which have differing peripheral device pattern arrangements, are formed in said dimensional measurement pattern region.

4. The semiconductor device, according to claim 1, wherein
said dimensional measurement pattern region is provided below metal interconnects of a semiconductor chip.

5. The semiconductor device, according to claim 1, wherein
said dimensional measurement pattern region is provided in a corner portion of a semiconductor chip.

6. The semiconductor device, according to claim 1, wherein
said dimensional measurement pattern region is provided in four corner portions of a semiconductor chip.

7. The semiconductor device, according to claim 6, wherein
peripheral pattern arrangement conditions of the dimensional measurement pattern are mutually the same in four corner portions of said dimensional measurement pattern region.

8. The semiconductor device, according to claim 6, wherein
peripheral pattern arrangement conditions of the dimensional measurement pattern mutually differ in four corner portions of said dimensional measurement pattern region.

9. The semiconductor device, according to claim 1, wherein
a structure is equipped in said dimensional measurement pattern region, allowing for measuring transistor characteristics having said dimensional measurement pattern.
